(19) United States
(12) Patent Application Publication
(10) Pub. No.: US 2026/0185857 A1
(43) Pub. Date: Jul. 2, 2026

(54) SENSOR ARRANGEMENT WITH INTEGRATED ELECTRONICS

(71) Applicant: Volkswagen Aktiengesellschaft, Wolfsburg (DE)

(72) Inventors: Heino Schiller, Braunschweig (DE); Simon Stutz, Hardegsen (DE); Paul Geisler, Braunschweig (DE); Tom Kruse, Bad Gandersheim (DE); Sven Maue, Salzgitter (DE)

(21) Appl. No.: 18/856,517

(22) PCT Filed: May 3, 2023
(86) PCT No.: PCT/EP2023/061715

§ 371 Date: Oct. 11, 2024

(30) Foreign Application Priority Data
May 18, 2022 (DE) 10 2022 204 944.6

(51) Int. Cl. G01F 1/60; G01F 1/58

(52) U.S. Cl. CPC G01F 1/60; G01F 1/586

(57) ABSTRACT

A sensor arrangement is provided, including a sensor portion with at least one sensor and an electronics portion containing electronics for controlling and/or reading data from the at least one sensor. The arrangement reduces the complexity and number of components in a fluid system by arranging the electronics portion on a rigid printed circuit board and the sensor portion on a flexible printed circuit board or configuring the sensor portion as a flexible printed circuit board.

### RELATED APPLICATIONS

The present application claims priority to International Patent Application No. PCT/EP2023/061715 to Heino Schiller et al., filed May 3, 2023, titled “Sensor Arrangement With Integrated Electronics,” which claims priority to German Patent Application No. 10 2022 204 944.6, filed May 18, 2022, the contents of each being incorporated by reference in their entirety herein.

### TECHNICAL FIELD

The present disclosure relates to a sensor array, comprising a sensor portion including at least one sensor and comprising at least one electronics portion including an electronic system for activating and/or reading out the at least one sensor, wherein the at least one sensor is electrically connected to the at least one electronic system. The present disclosure furthermore relates to a fluid system.

### BACKGROUND

Usually, various sensors and actuators are needed to control and diagnose the cooling circuit of a vehicle, the multitude of which increases the complexity of the thermal management system of the vehicle. The particular actuators and sensors, such as heating elements, temperature sensors and flow sensors, are typically designed as separate components and are individually installed at different installation positions in the vehicle. Due to the plurality of measuring sites as a result of the different installation positions, the complexity of the thermal management system also increases.

US 2014/0192483 A1 describes an arrangement that is produced in flexible printed circuit board technology. A flexible circuit board can be rolled, when needed, onto a passively or an actively cooled reel or can be unwound from this reel.

U.S. Pat. No. 5,818,692 A describes a flexible printed circuit board including fluid channels in which electronic components are disposed. The fluid channels can be connected to a cooling circuit so as to have the coolant flow around the electronic components.

A heating device for generating aerosols is known from WO 2021/140018 A1. The heater is arranged on a first portion of the flexible printed circuit board, and an activation electronic system is arranged on a second portion of the printed flexible circuit board.

EP 2 850 956 B1 describes a heating device in which a heating coil, together with heat reflecting elements, is arranged on a flexible foil. By rolling the flexible foil into a tube, the heating coil can be provided on the inside and the heat reflecting elements can be provided on the outside of the tube.

Furthermore, US 2015/0305146 A1 describes an arrangement comprising a flexible and stretchable substrate, which can be used in the electrical engineering field. In particular, the use in smart wearables is pointed out.

The known solutions are not designed for use in a vehicle environment and can, in particular, not reduce the complexity of existing thermal management systems.

### SUMMARY

Aspects of the present disclosure are directed to configuring a sensor array that reduces the complexity and the component diversity of existing thermal management systems in the vehicle. Certain aspects are disclosed in the respective subject-matter of the independent claims. Further implementations and preferred embodiments are the subject-matter of the dependent claims.

In some examples, a sensor array is disclosed, comprising a sensor portion including at least one sensor and at least one electronics portion including an electronic system for activating and/or reading out the at least one sensor. The at least one sensor is electrically connected to the at least one electronic system. In some examples, the electronics portion is arranged on a rigid printed circuit board. The sensor portion is arranged on a flexible printed circuit board or is designed in the form of a flexible printed circuit board.

As a result of the sensor array configurations, a sensor system, such as a sensor system for the integration into a cooling circuit, can be combined with a corresponding evaluation electronic system.

In some examples, a fluid system is disclosed, comprising at least one flowing fluid that flows through the fluid channel with a flow direction. The fluid system may include at least one sensor array according to the present disclosure, wherein the flexible printed circuit board of the sensor array is at least regionally arranged within the fluid channel. In this way, an integrated array including multiple sensors and/or actuators, combined with a corresponding electronic system, can be introduced into the fluid system. For example, the heating elements, combined with measuring electrodes for conductivity measurement, can be structured within the flexible printed circuit board so as to act on the fluid at a shared position and ascertain at least one measured variable.

In some examples, fluid system may be configured as a vehicle-side cooling system, a stationary cooling system, a flow-through water heater, a hand warmer, an industrial circuit system and the like.

### BRIEF DESCRIPTION OF THE DRAWINGS

Exemplary embodiments of the invention will be described hereafter in greater detail based on the drawings. In the drawings:

FIG. 1 shows a perspective representation of a sensor array according to some aspects of the present disclosure;

FIG. 2 shows a top view onto a sensor array according to some aspects of the present disclosure;

FIG. 3 shows a perspective representation of the sensor array from FIG. 2 in a form in which it is rolled into a spiral, according to some aspects of the present disclosure;

FIG. 4 shows a sectional representation of a sensor array according to the invention according to some aspects of the present disclosure; and

FIG. 5 shows a schematic representation of a fluid system according to some aspects of the present disclosure.

### DETAILED DESCRIPTION

In the figures, identical design elements have the identical reference numerals.

Flow sensors are typically expensive to produce, leading to their limited use in vehicle cooling systems. The sensor array described here can be configured as a flow sensor that is cost-effective to manufacture and can be easily integrated into cooling systems or other fluid systems.

The sensor array is constructed using rigid-flex printed circuit board technology. The electronic or power electronics system is mounted on a rigid printed circuit board, while the outer conductors of the rigid board extend into a flexible part, the flexible printed circuit board. These conductors are designed so that the flexible board can function, for example, as a heating element or a sensor. It is possible to integrate multiple sensors or actuators within the flexible printed circuit board.

Multiple components can thus be integrated into the sensor array, allowing temperature, pressure, or flow sensors to be cost-effectively embedded for controlling the fluid system. These sensors can provide more precise control of the fluid system and improve diagnostic capabilities. For instance, the pump speed and measured flow volume can be verified through a plausibility check during system operation. Thanks to the design of the sensor array, all variables are measured in approximately the same location, simplifying data evaluation by the electronics system.

Additional sensors can also be integrated into the flexible printed circuit board for diagnosing the medium, including sensors for conductivity measurements and impedance spectroscopy.

The sensor portion of the array can be entirely configured as a flexible printed circuit board, incorporating one or more sensors. This sensor array can be used in vehicle systems, such as a cooling system.

The sensor array's versatility increases when it includes at least one action portion, positioned next to the sensor portion. The action portion can function as an electric heater or a coil generating a magnetic field. The electronic system can activate the electric heater or coil continuously, intermittently, or cyclically. Traditional cooling system measurement setups consist of several components, but with this sensor array, multiple connectors and installation points can be eliminated, reducing costs and assembly time.

Conventional heaters often contain large amounts of metal, adding vehicle weight and increasing heating times due to thermal mass, which can also cause post-heating. These drawbacks can be avoided by using the sensor array's action portion, where the heating element can be implemented as flexible conductor tracks made from copper film.

In some examples, the action portion is integrated into the flexible printed circuit board alongside the sensor portion. Alternatively, multiple action portions and sensor portions can be integrated within the flexible printed circuit board, allowing cost-effective and compact measurement systems, such as Hall sensors.

The sensor array is further enhanced when at least one sensor in the sensor portion is configured as a capacitive sensor, resistive sensor, sensor electrode, or conductivity sensor. The flexible printed circuit board can contain discrete sensor elements or serve as part of one or more sensors. This configuration allows for the direct and cost-effective detection of fluid properties, with the flexible printed circuit board possibly extending into or contacting the medium.

In an advantageous design, the sensor array can also implement hot-film flow meters.

In some examples, the flexible printed circuit board is rolled into a spiral or tube shape. Rolling the board increases the active surface area of the sensor and action portions, and can induce turbulent flow for optimal heat transfer to the surrounding medium.

A tubular design of the flexible printed circuit board enables it to line the wall of a fluid channel, minimizing interaction between the sensor array and the fluid. The array can be tailored for either enhanced or minimized interaction with the fluid, depending on the requirements.

Other geometries for the flexible printed circuit board are also possible. For example, an action portion configured as a heating foil can be folded into compact shapes, such as Z, W, or L configurations, to optimize orientation within a fluid channel.

In some examples, the flexible printed circuit board incorporates reinforcement structures or spacer elements designed to maintain its bent or rolled shape. These reinforcement structures or spacer elements, preferably made from electrically insulating material, help achieve a stable geometry and fixed position for the flexible printed circuit board.

The sensor array can be optimally integrated into a fluid system when the flexible printed circuit board is positioned within a fluid flow. It can be oriented such that the flow direction runs parallel to the planar extension of the flexible printed circuit board, allowing optimal interaction between the flow and the sensors or actuators, such as heating elements.

In another example, the flexible printed circuit board is bent into a tube or tube segment, with at least two opposing action portions generating a magnetic field. Two sensor portions, rotated 90 degrees relative to the action portions, can measure Hall voltage in the fluid flow.

Additionally, coils and electrodes can be structured into the spirally rolled heating foil, arranged orthogonally in the rolled state. The heating foil forms part of one or more action portions. Coils can act as sensors or actuators, generating magnetic fields. These fields divert the conductive medium, and this diversion can be measured resistively or capacitively by the electrodes. This arrangement forms a magneto-inductive flow meter capable of determining the volume flow of the medium.

The sensor array can be introduced into the fluid system in a fluid-tight manner, with the flexible and rigid printed circuit boards mechanically and electrically connected by a connecting portion. This connecting portion can be either a flexible or rigid printed circuit board, depending on the design requirements.

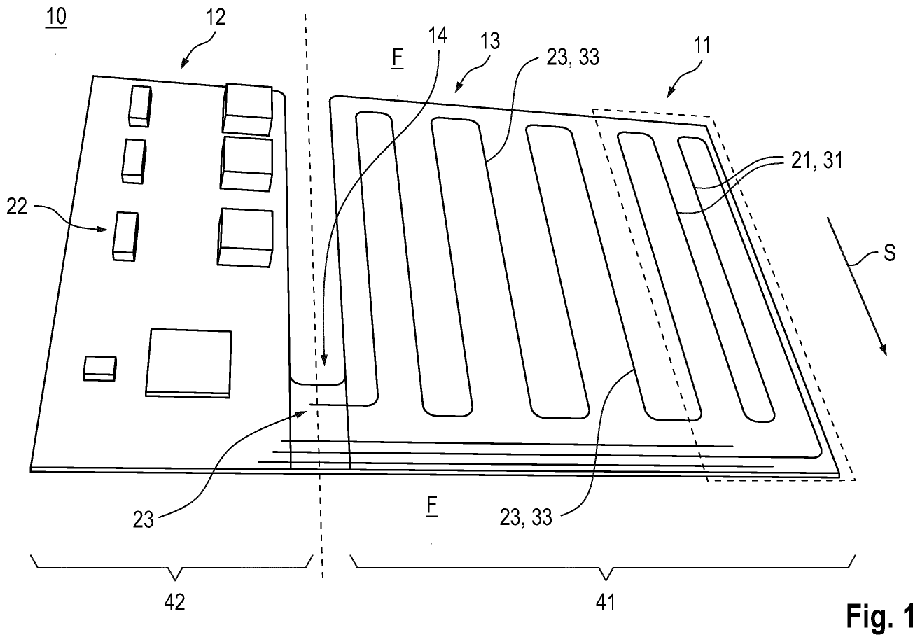

FIG. 1 shows a perspective representation of a sensor array 10 according to a first specific embodiment. In the exemplary embodiment depicted, the sensor array 10 comprises a sensor portion 11 that includes a sensor 21 and at least one electronics portion 12 that includes an electronic system 22 for activating and/or reading out the at least one sensor 21.

The sensor array 10 also includes an action portion 13. For example, the action portion 13 may be positioned between the electronics portion 12 and the sensor portion 11. Electrical conductor tracks 33 are located on the action portion 13, which may function as an electric heater 23.

The sensor portion 11 comprises electrical conductor tracks 31, that function as a capacitive sensor 21. In the exemplary embodiment depicted, the electrical conductor tracks 31 in the sensor portion 11 and the electrical conductor tracks 33 in the action portion 13 are electrically insulated on both sides and do not come into direct contact with a surrounding medium or fluid F.

The action portion 13 and the sensor portion 11 are arranged on a flexible printed circuit board 41. The electronics portion 12 is situated on a rigid printed circuit board 42. In addition to activating and evaluating the sensor 31 in the sensor portion 11, the electronic system 22 also manages the activation and control of the components in the action portion 13. In the exemplary embodiment shown, the electronic system 22 controls the electric heater 23.

Furthermore, a connecting portion 14 is provided, which mechanically and electrically connects the flexible printed circuit board 41 including the action portion 13 and the sensor portion 11, to the rigid printed circuit board 42, which includes the electronics portion 12.

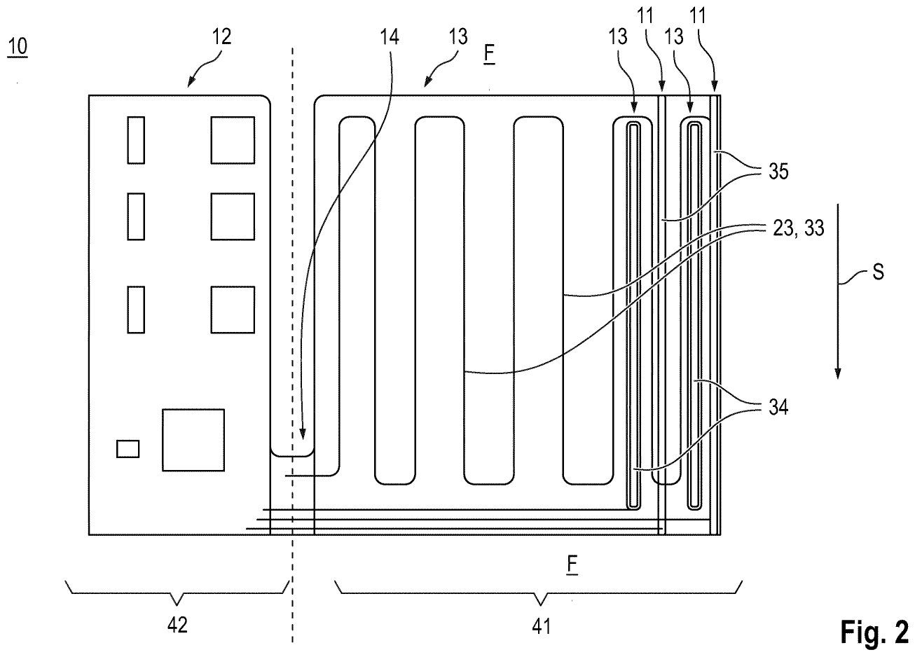

FIG. 2 shows a top view of a sensor array 10, depicted in a second specific embodiment. In contrast to the sensor array 10 described in FIG. 1, multiple action portions 13 are provided, alternating with multiple sensor portions 11.

On the side of the flexible printed circuit board that faces away from the electronics portion 12, electromagnetic exciter windings 34 and sensor electrodes 35 are alternately arranged following the electric heater 23. The sensor electrodes 35 are located in sensor portions 11, while the electromagnetic exciter windings 34 are placed in action portions 13. The sensor electrodes 35 and the electromagnetic exciter windings 34 are arranged and aligned with respect to one another on the flexible printed circuit board in such a way that, when rolled up, the two electromagnetic exciter windings 34 face one another, and the two sensor electrodes 35 likewise face one another. The sensor electrodes 35 may be rotated 90° with respect to the electromagnetic exciter windings 34 to implement a magnetoinductive flow meter.

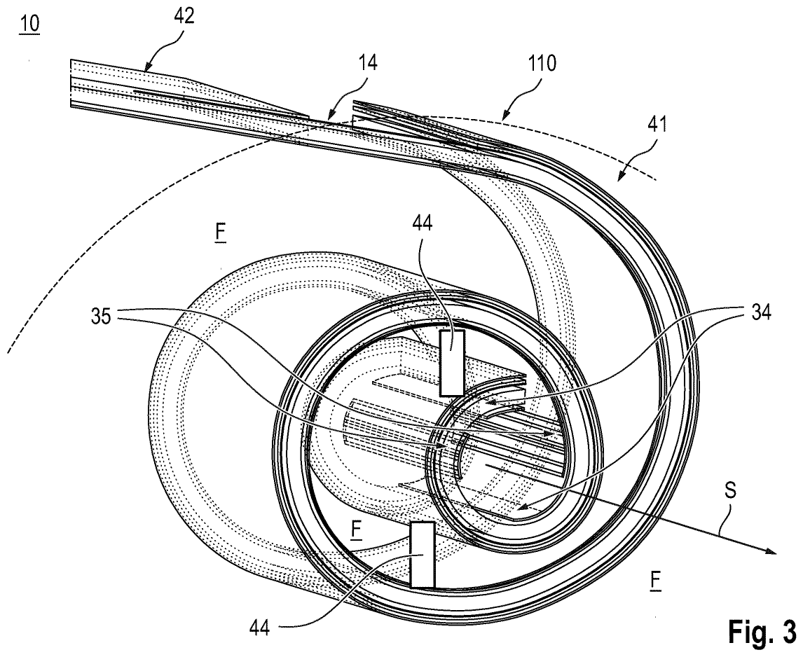

The specific sensor portions 11 and action portions 13 are arranged to be offset 90° about the flow direction S of the fluid F. [0048] FIG. 3 illustrates the sensor array 10 and the orientation of the electromagnetic exciter windings 34 and the sensor electrodes 35 relative to one another when rolled into a spiral. The fluid F can flow parallel to the planar extension of the flexible printed circuit board along the flow direction S. Notably, only the flexible printed circuit board may be immersed in the fluid F. The connecting portion 14 can be introduced into a feedthrough, which is not shown, thus electrically connect a fluid-conducting portion to a non-fluid-conducting portion of a fluid system 100.

In this exemplary embodiment, the sensor electrodes 35 are at least regionally arranged without electrical insulation (not shown) and are therefore in direct contact with the fluid F. The sensor electrodes 35 are thus designed as resistive sensors or as sensors for conductivity measurement.

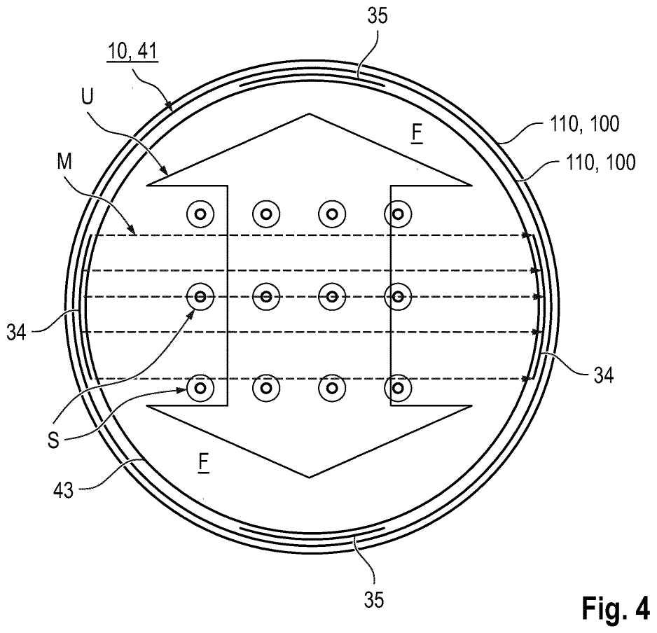

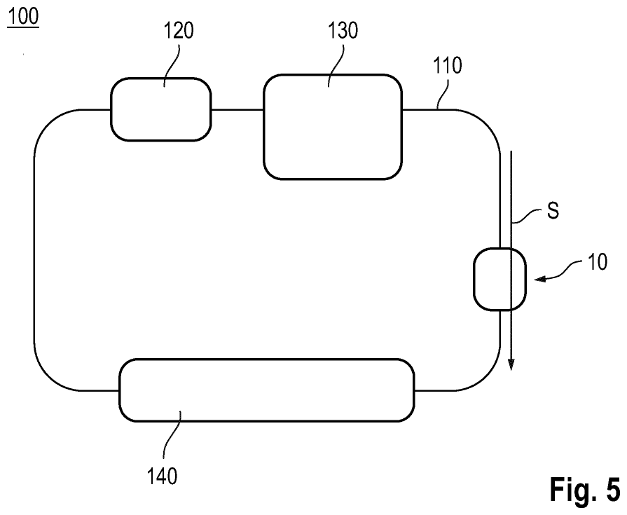

FIG. 4 shows a sectional representation of a sensor array 10 according to a third specific embodiment. FIG. 4 illustrates the principle and the mode of operation of the sensor array 10 from FIG. 2 and FIG. 3. In contrast to the exemplary embodiment shown in FIG. 3, the flexible printed circuit board of the sensor array 10 is rolled to form a tube. This allows the sensor array 10 to line the inside of a fluid channel 110 of a fluid system 100 shown in FIG. 5.

The electromagnetic exciter windings 34 generate a magnetic field with magnetic field lines M that extend transversely to the flow direction S of the fluid. A resulting Hall voltage U is induced by the magnetic field M in the fluid F. This Hall voltage U depends on the flow velocity along the flow direction S and is measured by the sensor electrodes 35. The corresponding measured data can be received and evaluated by the electronic system 22.

For clarity, the connecting portion 14 and the electronics portion 12 of the sensor array 10 are not shown.

Reinforcement structures 43 can be employed to maintain the rolled shape of the flexible printed circuit board 41. For example, a helical spring or a tube section can serve as a reinforcement structure 43. Additionally, spacer elements 44 can be used to ensure a spiral shape, as is shown in FIG. 3.

FIG. 5 shows a schematic representation of a fluid system 100 in one specific embodiment. The fluid system 100 is designed as a vehicle-side cooling system in the illustrated exemplary embodiment. The fluid system 100 is drastically simplified in the illustration and features a fluid channel 110 through which a fluid F, such as a liquid coolant, is pumped.

A coolant pump 120 may circulate the fluid F through the fluid channel 110 to transport heat from a heat generator 130, such as an internal combustion engine or a power electronics system, to a heat sink 140, such as an ambient heat exchanger.

The sensor array 10 is integrated into the fluid channel 110. A flexible printed circuit board 41, including the sensor portion 11 and optionally the action portion 13, is arranged within the fluid channel 110 while a rigid printed circuit board 42 including the electronics portion 12 is located outside the fluid channel 110.

The action portion 13 is designed to influence the fluid F in the fluid channel 110, through thermal or electromagnetic action.

The sensor portion 11 is designed to measure at least one parameter of the fluid F within the fluid channel 110.

### LIST OF REFERENCE SIGNS

100 motor vehicle
110 fluid channel
120 coolant pump/fluid pump
130 heat generator
140 heat sink
10 sensor array
11 sensor portion
12 electronics portion
13 action portion
14 connecting portion
21 sensor/capacitive sensor
22 electronic system
23 electric heater
31 electrical conductor tracks of the capacitive sensor
33 electrical conductor tracks of the electric heater
34 electromagnetic exciter winding
35 sensor electrode
41 flexible printed circuit board
42 rigid printed circuit board
43 reinforcement structure
44 spacer element
F fluid
M magnetic field
S flow direction of the fluid
U Hall voltage

1-10. (canceled)

11. A sensor array, comprising:
a sensor portion comprising at least one sensor;
at least one electronics portion comprising an electronic system for activating and/or reading out the at least one sensor, wherein the at least one sensor is electrically connected to the at least one electronic system;
wherein the electronics portion is arranged on a rigid printed circuit board; and
wherein the sensor portion is arranged on a flexible printed circuit board or is designed as a flexible printed circuit board.

12. The sensor array of claim 11, further comprising at least one action portion adjacent to the sensor portion, wherein the at least one action portion is configured as an electric heater and/or at least one coil for generating a magnetic field, and wherein the electronic system is configured to activate the electric heater and/or the at least one coil continuously, intermittently, or cyclically.

13. The sensor array of claim 12, wherein the at least one action portion is integrated into the flexible printed circuit board next to the sensor portion.

14. The sensor array of claim 11, wherein the at least one sensor is selected from the group consisting of a capacitive sensor, a resistive sensor, at least one sensor electrode, and a conductivity sensor.

15. The sensor array of claim 11, wherein the flexible printed circuit board is rolled to form a spiral or tube.

16. The sensor array of claim 11, wherein the flexible printed circuit board comprises a reinforcement structure and/or spacer elements configured to maintain the flexible printed circuit board in a bent and/or rolled shape.

17. The sensor array of claim 11, wherein the flexible printed circuit board is arranged within a fluid having a flow direction, and wherein the flexible printed circuit board is oriented such that the flow direction runs parallel to a planar extension of the flexible printed circuit board.

18. The sensor array of claim 17, wherein the flexible printed circuit board is bent to form a tube or tube segment, at least two opposing action sections for generating a magnetic field are arranged on the flexible printed circuit board, and at least two sensor portions for measuring a Hall voltage are positioned 90 degrees relative to the action sections about the flow direction.

19. The sensor array of claim 11, wherein the flexible printed circuit board and the rigid printed circuit board are mechanically and electrically connected via a connecting portion, wherein the connecting portion is flexible or rigid.

20. A fluid system, comprising:
at least one flowing fluid having a flow direction;
a fluid channel through which the at least one flowing fluid flows; and
at least one sensor array, comprising:
a sensor portion comprising at least one sensor;
at least one electronics portion comprising an electronic system for activating and/or reading out the at least one sensor, wherein the at least one sensor is electrically connected to the at least one electronic system;
wherein the electronics portion is arranged on a rigid printed circuit board;
wherein the sensor portion is arranged on a flexible printed circuit board or is designed as a flexible printed circuit board; and
wherein the flexible printed circuit board is at least regionally arranged within the fluid channel.

21. The fluid system of claim 20, further comprising at least one action portion adjacent to the sensor portion, wherein the at least one action portion is configured as an electric heater and/or at least one coil for generating a magnetic field, and wherein the electronic system is configured to activate the electric heater and/or the at least one coil continuously, intermittently, or cyclically.

22. The fluid system of claim 21, wherein the at least one action portion is integrated into the flexible printed circuit board next to the sensor portion.

23. The fluid system of claim 20, wherein the at least one sensor is selected from the group consisting of a capacitive sensor, a resistive sensor, at least one sensor electrode, and a conductivity sensor.

24. The fluid system of claim 20, wherein the flexible printed circuit board is rolled to form a spiral or tube.

25. The fluid system of claim 20, wherein the flexible printed circuit board comprises a reinforcement structure and/or spacer elements configured to maintain the flexible printed circuit board in a bent and/or rolled shape.

26. The fluid system of claim 20, wherein the flexible printed circuit board is arranged within the fluid having the flow direction, and wherein the flexible printed circuit board is oriented such that the flow direction runs parallel to a planar extension of the flexible printed circuit board.

27. The fluid system of claim 26, wherein the flexible printed circuit board is bent to form a tube or tube segment, wherein at least two mutually opposing action sections for generating a magnetic field are arranged on the flexible printed circuit board, and at least two sensor portions for measuring a Hall voltage are positioned 90 degrees relative to the action sections about the flow direction.

28. The fluid system of claim 20, wherein the flexible printed circuit board and the rigid printed circuit board are mechanically and electrically connected via a connecting portion, wherein the connecting portion is flexible or rigid.

29. A method for configuring a sensor array, comprising:
providing a sensor portion comprising at least one sensor;
providing an electronics portion comprising an electronic system for activating and/or reading data from the at least one sensor, wherein the at least one sensor is electrically connected to the at least one electronic system;
arranging the electronics portion on a rigid printed circuit board; and
arranging the sensor portion on a flexible printed circuit board or designing the sensor portion as a flexible printed circuit board.

30. The method of claim 29, further comprising:
configuring, via the electronic system, at least one action portion adjacent to the sensor portion, wherein the at least one action portion is configured as an electric heater and/or at least one coil for generating a magnetic field; and
activating the electric heater and/or the at least one coil continuously, intermittently, or cyclically.
